(19) United States
(12) Patent Application Publication
(10) Pub. No.: US 2007/0113162 A1
(43) Pub. Date: May 17, 2007

(54) Error code for wireless remote control device and method

(76) Inventor: Scott A. Lery, Nevada City, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/259,813

(22) Filed: Oct. 26, 2005

(51) Int. Cl. G06F 11/00; H03M 13/00

(52) U.S. Cl. 714/800

(57) ABSTRACT

A method and apparatus to provide error coding for remote control communications.

### TECHNICAL FIELD

This invention relates to the field of wireless remote controls and, in particular, to providing error coding for remote control communications.

### BACKGROUND

Conventional remote control technologies perform poorly with regard to command integrity. Command integrity refers, generally, to the transmission accuracy of a remote control command from a remote control transmitter to a remote control receiver. One source of transmission inaccuracy for remote control communications is interference. Although conventional wireless remote control protocols exist for both infrared (IR) and radio frequency (RF) devices, these conventional protocols do not effectively mitigate the effects of interference.

Some typical sources of IR interference include other IR devices, certain lighting fixtures such as fluorescent lighting ballasts, and reflections of the IR communication itself. RF interference typically originates from other RF devices. Interference from other RF devices is especially prevalent in applications where RF devices are widely used within communication distance of each other. For instance, remote controls for consumer electronics (e.g., televisions, computers, VCR players, DVD, players, CD players, cordless and cellular telephones, stereos, media centers, gaming consoles, set top boxes, etc.) and other consumer products (e.g. toys, etc.) and home or office equipment (e.g., air conditioners, lighting controls, garage doors, thermostats, etc.) are generally pervasive in residential neighborhoods, apartment complexes, commercial offices, and so forth. Interference among RF devices may be more difficult to prevent because the range of RF transmitters often extends beyond line-of-sight (LOS). In other words, one user's RF device may cause interference with another user's RF device, even though the users may be separated by distance and/or physical barriers (e.g., building walls, etc.).

Conventional wireless remote control technologies do little to address this problem of interference among devices. IR devices use LOS transmission, which restrict the user's orientation when attempting to control a device. Also, IR devices are typically preprogrammed to implement a command set that is unique to a particular controlled device. For example, a user may enter a code to designate a set of commands that are unique to a particular type of television. Although conventional IR devices employ a variety of different codes and data rates, using the correct command set for a particular controlled device does little to mitigate interference from outside sources that corrupt the transmission signal. Furthermore, using a specific command set does not prevent interference from another user using the same command set.

Conventional RF devices, on the other hand, have implemented remote control designs that offer some advantages over conventional IR devices. Conventionally, RF remote designs address the interference problem and, in particular, interference from multiple users, by using additional hardware to implement multiple transmission channels or frequencies. While using multiple channels may mitigate some interference problems, the additional hardware significantly increases the design and production cost of the RF devices. Frequencies available in a particular band may be limited as well. Conventional systems that share a frequency often suffer from interference generated by other devices. This ‘neighbor’ effect lowers overall system reliability.

Additionally, many conventional remote control receivers have a commercial analog front end that is data pattern sensitive. This sensitivity is common with inexpensive data slicer subsystems. Although such an inexpensive subsystem may help to reduce the overall cost of the receiver and remote control system, the associated data pattern sensitivity may introduce errors in transmissions that are not DC balanced. Some conventional devices use expensive hardware to avoid the data pattern sensitivity. Other conventional devices employ some form of line code such as Manchester code in the transmission protocol, but such line codes decrease information transmission efficiency. Furthermore, the use of a conventional scrambler is not effective in a packet system.

### BRIEF DESCRIPTION OF THE DRAWINGS

The present invention is illustrated by way of example, and not by way of limitation, in the figures of the accompanying drawings.

FIG. 1 illustrates one embodiment of communication system.

FIG. 2 illustrates one embodiment of a logical packet specification.

FIG. 3 illustrates one embodiment of a physical packet specification.

FIG. 4 illustrates one embodiment of a message timing protocol.

FIG. 5 illustrates one embodiment of an error detection system.

FIG. 6 illustrates one embodiment of a transmission method.

FIGS. 7A and 7B illustrate one embodiment of a reception method.

FIG. 8 illustrates one embodiment of an error encoding method.

FIG. 9 illustrates one embodiment of an error decoding method.

FIG. 10 illustrates one embodiment of an automatic pairing method.

FIG. 11 illustrates one embodiment of a manual pairing method.

### DETAILED DESCRIPTION

The following description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the spirit and scope of the present invention.

Embodiments of the present invention include various operations, which will be described below. These operations may be performed by hardware components, software, firmware, or a combination thereof. As used herein, the term “coupled to” may mean coupled directly or indirectly through one or more intervening components. Any of the signals provided over various buses described herein may be time multiplexed with other signals and provided over one or more common buses. Additionally, the interconnection between circuit components or blocks may be shown as buses or as single signal lines. Each of the buses may alternatively be one or more single signal lines and each of the single signal lines may alternatively be buses.

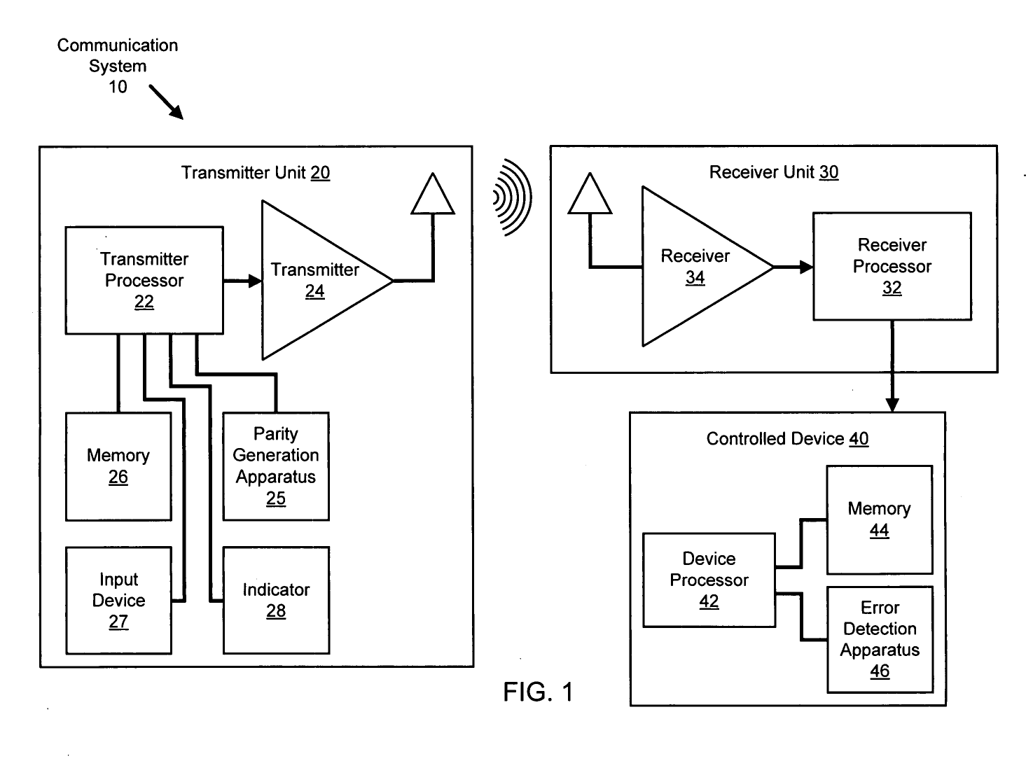

FIG. 1 illustrates one embodiment of communication system 10. The depicted communication system 10 includes a transmitter unit 20, a receiver unit 30, and a controlled device 40. In general, the transmitter unit 20 communicates a wireless remote control signal to the receiver unit 30 which, in turn, communicates the received remote control signal to the controlled device 40. Although the receiver unit 30 and the controlled device 40 are shown as separate components, other embodiments of the communication system 10 may include a controlled device 40 that incorporates the receiver unit 30 within the controlled device 40.

The transmitter unit 20 includes a transmitter processor 22, a transmitter 24, a parity generation apparatus 25, a data memory device 26, a user input device 27, and an indicator 28. The transmitter processor 22 performs processing operations on a remote control command to prepare the remote control command, and any associated data, for transmission to the receiver unit 30. In one embodiment, the transmitter processor 22 may be a simple (e.g., 8-bit) microprocessor embedded in the transmitter unit 20. In another embodiment, the transmitter processor 22 may be another type of general purpose or special purpose processing device.

The transmitter 24 converts the remote control signal from the transmitter processor 22 from a digital signal to an analog signal and transmits the analog signal as a wireless remote control signal. In one embodiment, the transmitter 24 may include a digital-to-analog converter (DAC) or other digital or analog circuitry to convert and transmit the remote control signal. In another embodiment, the transmitter 24 may be an analog, single carrier transmitter that modulates the remote control signal using amplitude shift keying (ASK), frequency shift keying (FSK), frequency modulation (FM), or another type of signal modulation.

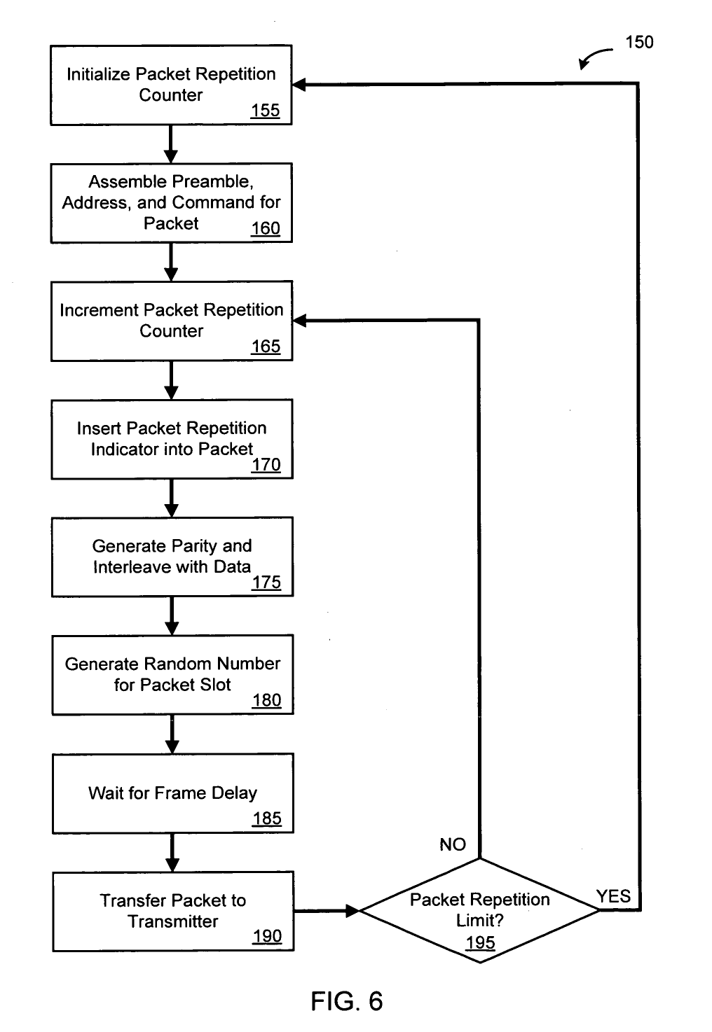

In one embodiment, the parity generation apparatus 25 generates an error code that may be associated with the remote control signal transmitted by the transmitter 24. In particular, the parity generation apparatus 25 may append or otherwise attach a parity code to the remote control command. In one embodiment, the error code may be an error detection code. In another embodiment, the error code may be an error correction code. One example of the parity generation apparatus 25 is shown and described in more detail with reference to FIG. 5.

In one embodiment, the data memory device 26 stores data which may be used by the transmitter processor 22 to assemble and/or process the remote control signal. For example, the memory 26 may store control instructions, data, a set of remote control commands, error detection and/or correction codes, an error coding table, and other types of data and metadata that the transmitter processor 22 may use to operate the transmitter unit 20.

In one embodiment, the user input device 27 allows a user to input codes and commands to the transmitter unit 20. Such codes and/or commands may facilitate operation of the transmitter unit 20, the receiver unit 30, or the controlled device 40. In certain embodiments, the input device 27 may include hardware and/or software, including physical buttons, touchscreens, voice recognition, a keypad, and so forth.

In one embodiment, the indicator 28 communicates a signal to a user. The signal may be an audio signal and/or a visual signal. For example, the indicator 28 may be a light such as a light emitting diode (LED), a liquid crystal display (LCD) or other display screen, an audio speaker, and so forth.

The receiver unit 30 receives the wireless remote control signal from the transmitter unit 20. In one embodiment, the receiver unit 30 may be a set top box such as the MediaPortal™ or MediaScout™ available from 2Wire, Inc., of San Jose, Calif. Alternatively, the receiver unit 30 may be another type of receiver unit. For example, the set top box may be a stand-alone digital subscriber line (DSL) modem which employs DSL mode along with other media components to combine television (Internet Protocol TV or Satellite) with broadband content from the Internet to bring the airwaves and the Internet to the controlled device 40 such as an end user's television set. A multiple carrier communication channel connected to the set top box may communicate a signal to a residential home. The home may have a home network such as Ethernet. The home network may either use the multiple carrier communication signal directly or convert the data from the multiple carrier communication signal to another usable signal. The set top box also may include an integrated Satellite and Digital Television Receiver, High-Definition Digital Video Recorder, Digital Media Server. In another embodiment, the set top box also may include a storage medium, one or more communication ports, an integrated user interface, and other components.

The illustrated receiver unit 30 includes a receiver processor 32 and a receiver 34. In one embodiment, the receiver processor 32 is substantially similar to the transmitter processor 22. The receiver processor 32 processes remote control signals from the receiver 34 and communicates the remote control signals to the controlled device 40. The receiver 34 converts the remote control signal from an analog signal to a digital signal and transmits the digital signal to the receiver processor 32. In one embodiment, the receiver 34 may be similar to the transmitter 24. In another embodiment, the receiver 34 may include an analog-to-digital converter (ADC) or other digital or analog circuitry to receive and convert the remote control signal. For example, the receiver 34 may include an averaging circuit, a threshold slicer, and other similar circuitry. Additionally, the receiver 34 may be integral to the receiver unit 30, as shown, or alternatively independent from and coupled to the receiver unit 30. In other words, the receiver 34 may be located within a set top box or, alternatively, external to a set top box.

The illustrated controlled device 40 is representative of one or more electronic devices that may process or be controlled by the remote control command from the transmitter unit 20. As examples, the controlled device 40 may be a television, a set top box, a radio, a DVD player, a VCR, a CD player, a computer, a media center, a hobby/toy car, a garage door opener, a thermostat, a car entry system, commercial door entry systems such as those found in offices or hotels, lighting systems, or another similar system. Although several exemplary controlled devices 40 are listed, the controlled device 40 may be any other type of device that may be controlled by a wireless remote control signal or may facilitate remote control communications.

The illustrated controlled device 40 includes a device processor 42, a data memory device 44, and an error detection apparatus 46. In one embodiment, the device processor 42 may be substantially similar to the transmitter processor 22 and the receiver processor 32. In another embodiment, the device processor 42 may be another type of processor, such as a central processing unit (CPU), which performs other operations within the controlled device 40.

Similarly, the memory device 44 may be substantially similar to the memory device 26 of the transmitter unit 20. In one embodiment, the memory device 44 may store control instructions, data, a set of remote control commands, error detection and/or correction codes, an error coding table, and other types of data and metadata that the device processor 42 may use to operate the controlled device 40.

In one embodiment, the error detection apparatus 46 detects and/or corrects errors that may occur in the transmission of the remote control signal from the transmission unit 20 to the controlled device 40. Although the error detection apparatus 46 is shown and described as a component of the controlled device 40, other embodiments of the communication system 10 may include the error detection apparatus 46 within the receiver unit 30. Additionally, the receiver unit 30 may be included in the controlled device 40, as described above. In particular, the error detection apparatus 46 may detect an error code that is appended or otherwise attached to the remote control command and potentially correct a transmission error in the remote control command. In one embodiment, the error code may be an error detection code. In another embodiment, the error code may be an error correction code. One example of the error detection apparatus 46 is shown and described in more detail with reference to FIG. 5.

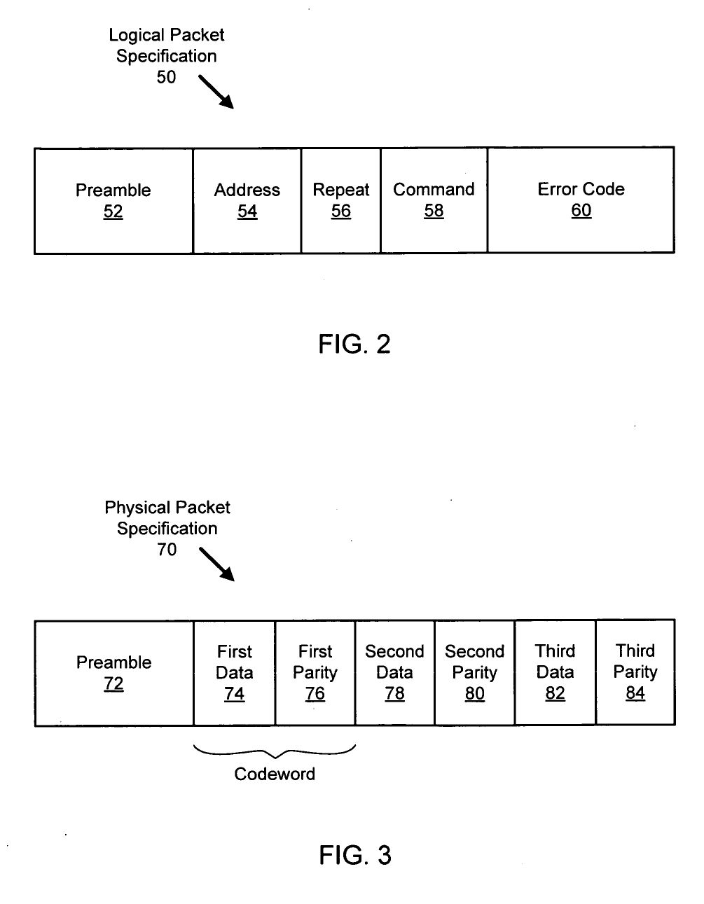

FIG. 2 illustrates one embodiment of a logical packet specification 50. The illustrated logical packet specification 50 includes a preamble field 52, a transmitter address field 54, a packet repetition field 56, a command field 58, and an error code field 60. Other embodiments of the logical packet specification 50 may include fewer or more fields.

The preamble field 52 stores a preamble. The receiver unit 30 may determine bit sampling timing by detecting the preamble. In one embodiment, the preamble is a multi-bit sequence that identifies every communication from the transmitter unit 20 to the receiver unit 30. For example, the preamble may be a 16-bit sequence. In another embodiment, the preamble may be more or less than sixteen bits. In one embodiment, the preamble may be DC-balanced so that it contains an equal number of high and low bit signals. One example of a 16-bit, DC-balanced preamble is 1010101001110010, although other DC-balanced preambles may be used. Alternatively, the preamble may be non-DC-balanced. In one embodiment, the preamble may be defined to have good autocorrelation properties, regardless of DC-balancing. One example of a 15-bit, non-DC-balanced preamble with good autocorrelation properties is 101010101110010, although other non-DC-balanced preambles may be used.

The transmitter address field 54 stores a transmitter address that uniquely identifies the transmitter unit 20. The transmitter address may be automatically assigned or assigned by a user. In one embodiment, the transmitter address is a multi-bit address. For example, the transmitter address may be a 10-bit address. Other embodiments may have more or less bits.

The packet repetition field 56 stores a packet repetition indicator. In certain embodiments, the transmitter unit 20 may transmit the remote control signal to the receiver unit 30 multiple times. In order to distinguish among the multiple transmissions, the packet repetition indicator may identify the transmission iteration. For example, the second transmission of a packet may have a packet repetition indicator with a value of two to indicate that the transmission is the second of multiple transmissions. In one embodiment, the packet repetition indicator may be a multi-bit sequence having sufficient bits to distinguish among the number of repetitions. For example, a packet that will be transmitted three times may have a packet repetition indicator that is two bits in length (allowing for up to four transmissions). Other embodiments may include more or less bits. Where the transmitter unit 20 only transmits the remote control signal once, rather than multiple times, the packet repetition indicator may be ignored or the packet repetition field 56 may be dropped altogether from the packet.

The command field 58 stores a remote control command. As described above, the remote control command is used by the controlled device 40 to perform an operation according to the command from the transmitter unit 20. In one embodiment, the command may be a multi-bit command. For example, the command may be a 12-bit command that allows 4096 distinct command combinations. Other embodiments may use more or less bits and allow more or less command combinations. Although not shown, the logical packet specification 50 may include other data control bits such as balance, pairing, and toggle bits. In one embodiment, these bits may be included in the command.

The error code field 60 stores an error code to allow the receiver unit 30 (or the controlled device 40) to verify that the transmission is free of errors, as well as to potentially correct any such errors. The error code may include only parity or may include data and parity, for example, in an alternating or interleaved manner. In one embodiment, the error code may be a multi-bit error code. For example, the error code may be a 24-bit error code. In one embodiment, the bit length of the error code may depend on the total bit length of the data fields, including the transmitter address field 54, the packet repetition field 56, and the command field 58. For example, the error code may include one byte (eight bits) for every byte of data. Therefore, a logical packet specification 50 having a 10-bit transmitter address field, 2-bit packet repetition field 56, and a 12-bit command field 58 (for a total of 24 bits) may include a 24-bit error code field 60. However, other embodiments may have different ratios between the preamble field 52, the data fields 54-58, and the error code field 60. Furthermore, the bit length of the error code field 60 may depend on the type of error code employed. Two exemplary error code technologies that may be used include the Nordstrom-Robinson code and the Golay code, although other types of error detection or error correction codes may be used.

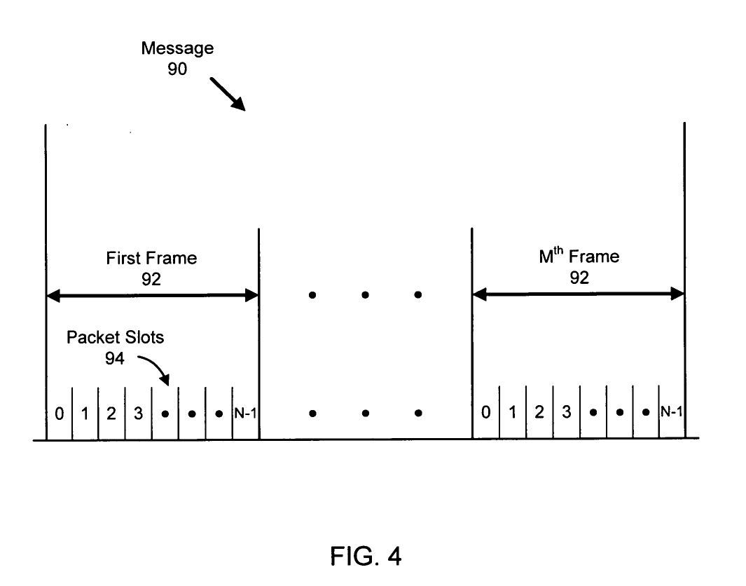

FIG. 3 illustrates one embodiment of a physical packet specification 70. The illustrated physical packet specification 60 includes a preamble block 72, a first data block 74, a first parity block 76, a second data block 78, a second parity block 80, a third data block 82, and a third parity block 84. Each pair of data and parity blocks may be referred to as a codeword. One example of a codeword is the combination of the first data block 74 and the first parity block 76.

Although a particular number of data and parity blocks are shown, other embodiments of the physical packet specification 70 may include fewer or more data and/or parity blocks. In another embodiment, the physical packet specification 70 may have an unequal number of data and parity blocks. Furthermore, the data and parity blocks may equal in size (e.g., 1 byte per block) or may be unequal in size compared to each other and compared to other blocks of the same type (i.e., the first data block 74 may have fewer or more bits than the first parity block 76 and/or the second data block 78).

In one embodiment, the data blocks 74, 78, 82 are generated from the transmission address, the packet repetition indicator, and the command. In another embodiment, the data blocks 74, 78, 82 also may include other data such as balance bits, pairing bits, toggle bits, or other control bits. Similarly, the parity blocks 76, 80, 84 may be generated from or as a part of the error code. The illustrated physical packet specification 70 shows the data blocks 74, 78, 82 interleaved with the parity blocks 76, 80, 84. One potential advantage of interleaving the data and parity blocks 74-84 is to approach a DC-balanced transmission of the data packet. For example, if the preamble is DC-balanced and the error code is DC-balanced, then the interleaved data packet is substantially DC-balanced, even if the data blocks 74, 78, 82 are not completely DC-balanced. In another embodiment, two or more parity blocks 76, 80, 84 may be located adjacent to one another within the physical packet specification 70. Alternatively, other embodiments of the physical packet specification 70 may be implemented.

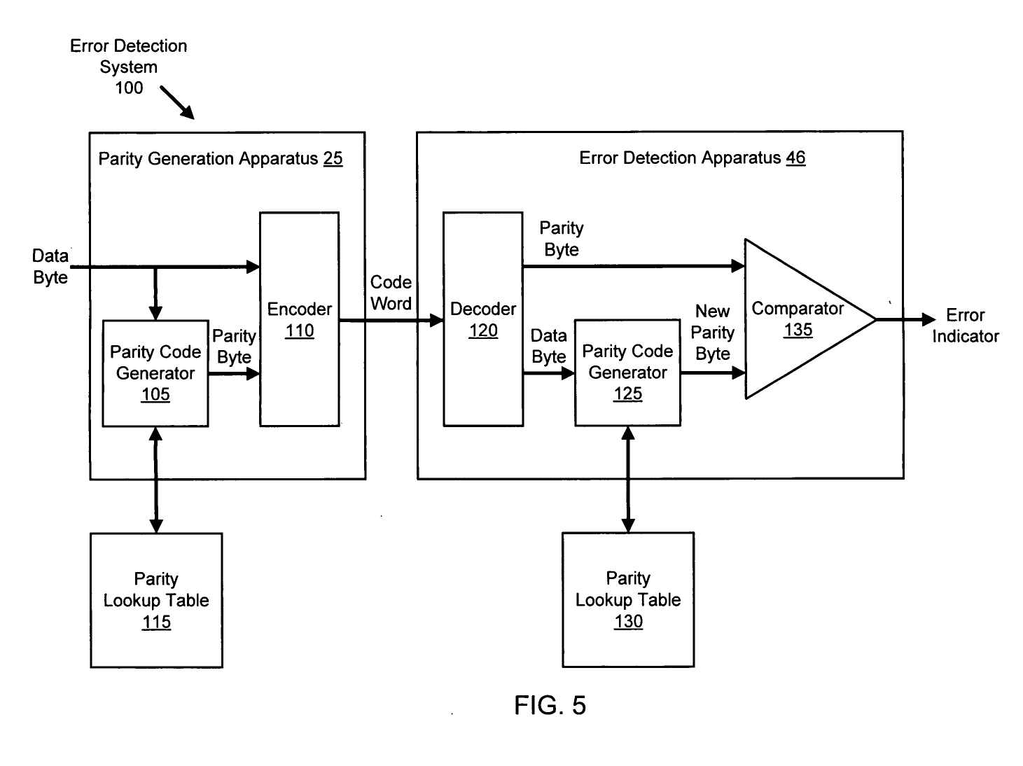

FIG. 4 illustrates one embodiment of a message timing protocol. The message timing protocol is described with reference to a single transmission message 90, which includes multiple frames 92. Each frame 92 defines a plurality of packet slots 94. Each packet slot 94 is of adequate time to transmit a data packet such as a data packet having the physical packet specification 70 shown in and described with reference to FIG. 3.

The illustrated message 90 includes M frames 92, and each frame 92 includes N packet slots 94 (zero through N−1). The total number of packet slots 94 for the message 90 is M*N. In one embodiment, each frame 92 is a repetition of the first frame 92. Alternatively, the frames 92 may vary from one to the next. As one example, the message 90 may have three frames 92 (M=3) and eight packet slots 94 (N=8) per frame 92. The data packet may be transmitted in the second packet slot 94 of each frame 92. In this example, the message 90 includes three transmissions of the data packet, each transmission occurring in the same packet slot 94 (packet slot 2) of each of the frames 92. In other embodiments, the message 90 may include fewer or more frames 92 and fewer or more packet slots 94 per frame 92. In one embodiment, the number of frames 92 per message 90 and packet slots 94 per frame 92 may be predetermined or defined by a user. In another embodiment, each transmission may occur in a different packet slot 94 of each of the frames 92. For example, the transmission may occur in the second packet slot 94 of the first frame 92, the sixth packet slot 94 of the second frame 92, and the fifth packet slot 94 of the third frame 92.

A tradeoff exists between packet detection and prevention of false positive communications. A false positive communication may be received from a user of another nearby remote control system. Alternatively, a false positive communication may originate from an interference source, as described above. Either way, a false positive communication received from outside the communication system 10 may cause the controlled device 40 to operate improperly (e.g., change channels, adjust settings, etc.). Where the message 90 includes multiple frames 92, the controlled device 40 may implement the transmitted command if at least one of the frames 92 includes a detected command. In an alternative embodiment, the controlled device 40 may implement the transmitted command only if multiple error-free data packets are received. Although requiring multiple repetitions of the data packet may increase the time delay between initial transmission and execution of the command, the repetition requirement lowers the possibility of executing a command based on a false positive communication.

The logical packet specification 50 and the physical packet specification 70 described above, in conjunction with the message timing protocol of FIG. 4, illustrate only one of many configurations that might be implemented in the communication system 10. The logical packet specification 50 and the physical packet specification 70 described above may be implemented in a radio frequency remote control system 10, or other communication system, in order to provide a certain level of performance. In one embodiment, the described combination may provide low probability for false positive communications. For example, the combination may limit false positive communications to less than one per day, assuming the presence of seven other users (disturbers) within range of the communication system 10. In another embodiment, the combination may provide a relatively high probability of message (command) detection. For example, the probability of message detection may be greater than 90 percent in an environment with seven disturbers. In another embodiment, the combination may limit message latency. For example, the message latency may be about 250 ms or less where M=8, N=3, and the data rate is 6 kbps. In another embodiment, the combination may be suitable for use with relatively slow data rates. For example, the data rate of the communication system 10 may be approximately 10 kbps or less. Alternatively, the data rate may be another standard data rate similar to conventional remote control systems. In another embodiment, the combination may provide good DC balance so that off-the-shelf commercial wireless radio frequency components may be used. Alternatively, expensive or custom components may be used. Although specific examples of combinations and potential advantages are provided herein, other combinations of logical or physical data arrangements and/or protocols may be implemented.

FIG. 5 illustrates one embodiment of an error detection system 100. The illustrated error detection system 100 includes the parity generation apparatus 25 and the error detection apparatus 46. The error detection system 100 is shown in a logical configuration and may exclude some intermediary or accessory components that may facilitate the operations of the error detection system 100. Furthermore, the operation of the error detection system 100 is described in terms of bytes, but other embodiments may process data in other blocks of data, including bits, words, and so forth.

The parity generation apparatus 25 receives a data byte as input to a parity code generator 105 and an encoder 110. In one embodiment, the parity code generator 105 generates an error code associated with the data byte. For example, the parity code generator 105 may reference a parity lookup table 115 to generate a parity byte. The parity lookup table 115 may be stored on the memory device 26 or on another storage or memory device coupled to the transmitter unit 20. Alternatively, the parity code generator 105 may implement other software and/or hardware to generate the error code. Further reference to the parity byte refers to one or more parity bytes of the error code generally and is not limited to a single byte.

The encoder 110 receives the data byte and the parity byte as input and outputs a codeword. In one embodiment, the codeword is a combination of the parity byte appended to the data byte. Alternatively, the data and parity bytes may be combined in another manner. One example of a codeword is shown in FIG. 3. The parity generation unit 25 then communicates the codeword, either directly or indirectly, to the error detection apparatus 46. In another embodiment, the transmitter unit 20 may transmit multiple codewords, as well as other data, in a single transmission.

The error detection apparatus 46 receives the codeword and inputs the codeword to a decoder 120 which separates the data byte and the parity byte. The decoder 120 communicates the data byte to a parity code generator 125 to generate a new parity byte. In one embodiment, the parity code generator 125 is substantially similar to the parity code generator 105 of the parity generation apparatus 25. For example, the parity code generator 125 may reference a parity lookup table 130 which is similar to the parity lookup table 115. In one embodiment, the parity lookup table 130 may be stored on the memory device 44 of the controlled device 40 or another storage or memory device of the controlled device 40 or the receiver unit 30.

A comparator 135 subsequently receives and compares the transmitted parity byte and the new parity byte and outputs an error indicator. In one embodiment, the error indicator indicates if there is a difference between the transmitted parity byte and the new parity byte, which difference, if any, corresponds to an error in the transmitted data byte.

One exemplary error code that may be used to generate the parity byte is the Nordstrom-Robinson code. The Nordstrom-Robinson code is a binary nonlinear (16,8,6) code with a relatively large number of possible codewords (2⁸=256 codewords) given the length (16-bit codeword) and minimum distance (6 bits). The following listing is a decimal representation of a parity lookup (encoding) table such as the parity lookup tables 115, 130, which may be used to generate the error code for a given data byte.
{0,118,185,207,109,216,23,162,158,43,228,81,243,133,74,60, 234,147,92,37,180,14,193,123,71,253,50,136,25,96,175,214, 213,172,99,26,139,49,254,68,120,194,13,183,38,95,144,233, 63,73,134,240,82,231,40,157,161,20,219,110,204,186,117,3, 91,225,46,148,198,191,112,9,53,76,131,250,168,18,221,103, 141,56,247,66,35,85,154,236,208,166,105,31,126,203,4,177, 178,7,200,125,28,106,165,211,239,153,86,32,65,244,59,142, 100,222,17,171,249,128,79,54,10,115,188,197,151,45,226,88, 167,29,210,104,58,67,140,245,201,176,127,6,84,238,33,155, 113,196,11,190,223,169,102,16,44,90,149,227,130,55,248,77, 78,251,52,129,224,150,89,47,19,101,170,220,189,8,199,114, 152,34,237,87,5,124,179,202,246,143,64,57,107,209,30,164, 252,138,69,51,145,36,235,94,98,215,24,173,15,121,182,192, 22,111,160,217,72,242,61,135,187,1,206,116,229,156,83,42, 41,80,159,230,119,205,2,184,132,62,241,75,218,163,108,21, 195,181,122,12,174,27,212,97,93,232,39,146,48,70,137,255}

The index of the above listing may be the 8-bit data byte, in which case the output of the listing is an 8-bit parity byte. Thus, a 16-bit codeword may be formed from the combination of the input data byte and output parity byte. For example, if the data byte is 00001110 (decimal 14), then the corresponding parity byte according to the Nordstrom-Robinson code is 01001010 (decimal 74). The resulting codeword is 0000111001001010. Table 1 shows the pertinent portions of the parity lookup table listing corresponding to the above codeword.

TABLE 1
Parity Lookup Table for Codeword 0000111001001010
(decimal 14-74).

| Data | Parity |
|---|---|
| 0 | 0 |
| 1 | 118 |
| 2 | 185 |
| 3 | 207 |
| . | . |
| . | . |
| . | . |
| 12 | 243 |
| 13 | 133 |
| 14 | 74 |
| 15 | 60 |
| 16 | 234 |
| 17 | 147 |
| . | . |
| . | . |
| . | . |
| 250 | 39 |
| 251 | 146 |
| 252 | 48 |
| 253 | 70 |
| 254 | 137 |
| 255 | 255 |

Furthermore, the Nordstrom-Robinson code is systematic and, therefore, the parity lookup table may be half the size of an equivalent non-systematic code. For example, the parity lookup table may be 256×8 instead of 256×16.

In one embodiment, the first and last codewords (associated with parity corresponding to decimal 0 and 255) may be avoided because they are not DC balanced, although the average DC balance of the parity lookup table listing is zero. Although certain embodiments may employ the Nordstrom-Robinson code, other embodiments may use other codes such as the Golay code or another similar code. The Golay code is a (24,12,8) code that may be implemented in a table of size 2048×12.

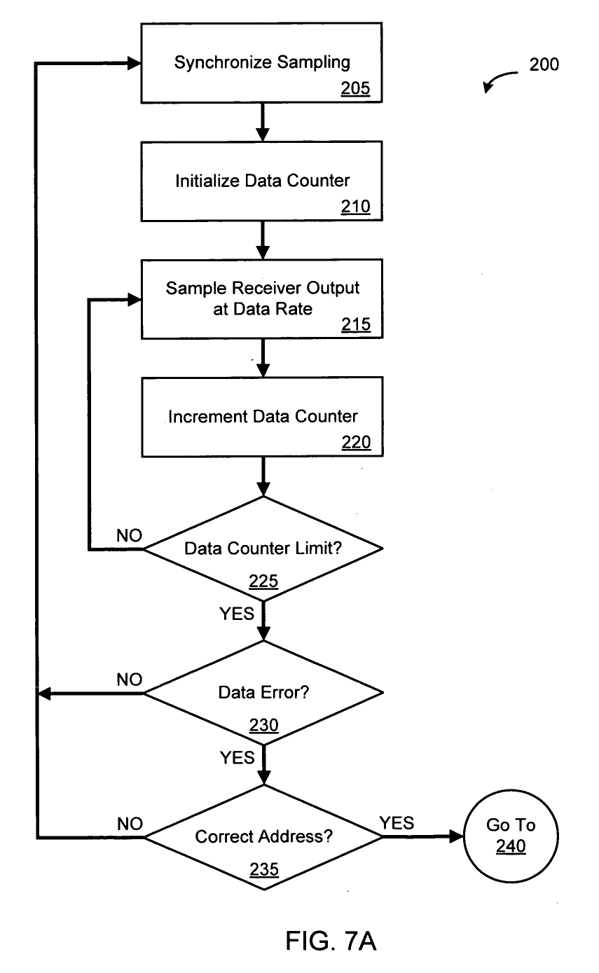

FIG. 6 illustrates one embodiment of a transmission method 150. Although the following description of the transmission method 150 references the communication system 10, the communication system 10 is only representative and embodiments of the transmission method 150 may be implemented in other types of communication systems.

The transmission method 150 begins and the transmitter processor 22 initializes 155 a packet repetition counter. For example, the transmitter processor 22 may initialize 155 the packet repetition counter to zero. In one embodiment, the packet repetition counter may be stored on the memory device 26. The transmitter processor 22 then assembles 160 the preamble and at least some of the data, including the transmitter address and the command, as well as any control bits. In one embodiment, the transmitter processor 22 only assembles 160 the preamble, transmitter address, and command once per message time. The transmitter processor 22 subsequently increments 165 the packet repetition counter and inserts 170 the packet repetition indicator into the data packet with the preamble and other data.

The transmitter processor 22 then generates 175 an error code corresponding to the data and interleaves the parity with the data. In one embodiment, the error code inherently interleaves the data and the parity. One example of the interleaved data and parity blocks is shown and described with reference to FIG. 3. The transmitter processor 22 then generates 180 a random number corresponding to one of the packet slots 94 to indicate the packet slot 94 within each frame 92 to transmit the data packet. For example, if there are eight packet slots 94 in each frame 92, the transmitter processor 22 may generate a random number in the interval [0,7]. The transmitter processor 22 then waits 185 for a frame delay until the indicated packet slot 94, at which time the transmitter processor 22 transfers 190 the data packet to the transmitter 24 for transmission.

The transmitter processor 22 then determines 195 if the packet repetition counter exceeds a packet repetition limit and, if so, returns to initialize 155 the packet repetition counter in anticipation of a subsequent message. Otherwise, if the packet repetition counter does not exceed the packet repetition limit, the transmitter processor 22 proceeds to increment 165 the packet repetition counter and retransmit the data packet, as described above. In one embodiment, the data packet may be transmitted in the same packet slot 94 of each frame 92. Alternatively, the data packet may be transmitted in different packet slots 94 of each frame. For example, the packet slot 94 for a give frame may be determined by a random or pseudorandom generator. The depicted transmission method 150 continues until all of the frames 92 of a message 90 have been transmitted. For example, if a message 90 has three frames 92, the transmission method 150 will transmit the data packet three times before returning to process a subsequent message.

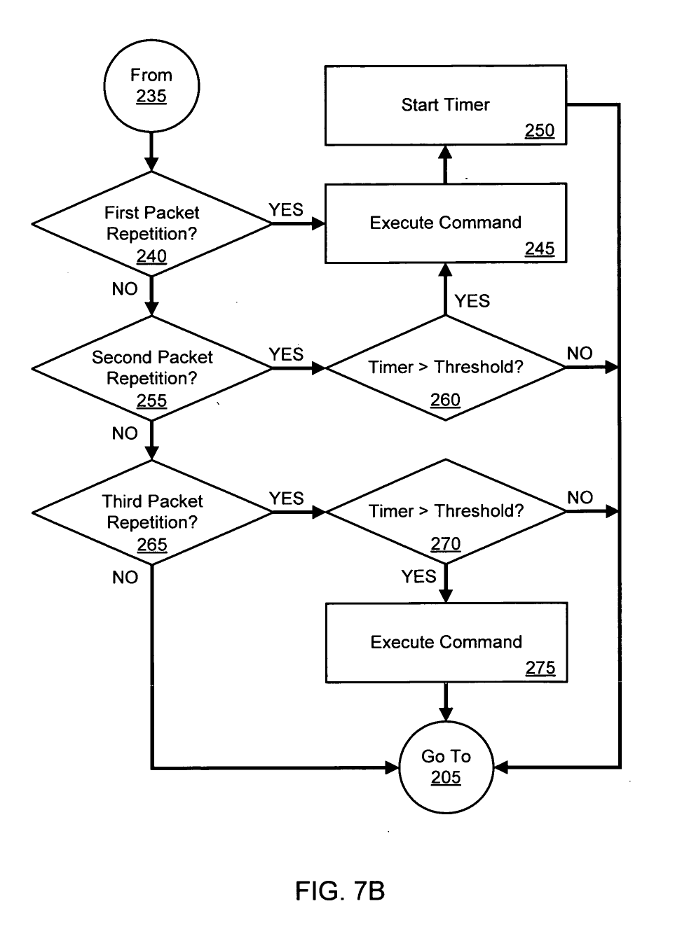

FIGS. 7A and 7B illustrate one embodiment of a reception method 200. Although the following description of the reception method 200 references the communication system 10, the communication system 10 is only representative and embodiments of the reception method 200 may be implemented in other types of communication systems.

The illustrated reception method 200 begins in response to receiving the preamble from which bit timing is derived. The receiver processor 32 then synchronizes 205 the sampling so that the receiver processor 32 can distinguish and process the individual bits of the transmitted data packet. In one embodiment, detecting the preamble and synchronizing 205 the sampling may include sampling the output of the receiver 34 at an accelerated sampling rate (e.g., eight times the transmission data rate), correlating the sampled output, and adjusting the sample timing to locate the sampling occurrence in approximately the center of a bit period. Alternatively, other synchronization operations may be implemented in place of or in addition to these exemplary synchronization operations.

The receiver processor 32 then initializes a data counter. In one embodiment, the receiver processor 32 initializes 210 the data counter to zero. The receiver processor 32 subsequently samples 215 the output of the receiver 34 at the transmission data rate. For example, if the transmission data rate is 10 kbps, the receiver processor 32 may sample the output of the receiver 34 at 10 kbps.

After sampling 215 each data bit, the receiver processor 32 increments 220 the data counter and determines 225 if the data counter exceeds a data counter limit. The data counter limit corresponds to the number of bits in the message so that the receiver processor 32 can process the correct number of bits after receiving the preamble. If the receiver processor 32 determines 225 that the data counter does not exceed the data counter limit, then the receiver processor 32 continues to sample 215 the receiver output until the correct number of bits have been sampled and the data counter exceeds the data counter limit. For example, if the data and parity blocks of the message include a total of 48 bits (six bytes), then the receiver processor samples all 48 bits before the data counter exceeds the data counter limit, which is set to 48.

After the data counter exceeds the data counter limit, the receiver processor 32 may determine 230 if the transmitted data is free of transmission errors. In one embodiment, the receiver processor 32 compares the transmitted parity bits and a new parity byte generated using the transmitted data bits. In other words, the receiver processor 32 uses the transmitted parity bits to generate a new error code, including new parity bits, and then compares the new parity bits to the transmitted parity bits. If the two parity bytes differ then the transmitted data bits contain one or more errors. If the data contains errors, then the receiver processor 32 discards the received data and restarts the reception method 200. However, if the data is error-free, then the receiver processor 32 extracts the transmitter address from the data and determines 235 if the received transmitter address is correct (i.e., the address corresponds to the communication system 10 and not to another system). If the received transmitter address is not correct, then the receiver processor 32 discards the received data and restarts the reception method 200. Alternatively, if the received transmitter address is correct, the receiver processor 32 continues as shown in FIG. 7B.

In particular, the remainder of the reception method 200 handles packet repetition. In one embodiment, the controlled device 40 may execute the command as long as one packet is received without errors. In this embodiment, subsequent packets are discarded. In an alternative embodiment, the controlled device 40 may execute the command only if multiple error-free packets are received. The remaining operations of the reception method 200 illustrate the former scenario where only one error-free data packet is received, but is representative of other protocols where multiple packets are received.

The receiver processor 32 determines 240 if the current packet is the first data packet. In one embodiment, the receiver processor 32 may reference the packet repetition indicator of the data packet. If the data packet is the first data packet in a series, then the controlled device 40 executes 245 the command received in the first data packet. The receiver processor 32 also starts 250 a timer. The timer is used to prevent discarding a packet during the current frame, when a packet was missed in the previous frame, and to also to prevent repeating a command. The receiver processor 32 then restarts the reception method 200.

If the current packet is the second data packet, the receiver processor 32 determines if the timer exceeds a threshold equal to the time it takes to send a message and, if so, executes 245 the command and starts the timer 250. However, if the timer does not exceed the threshold, the receiver processor 32 restarts the reception method 200. Similarly, if the current packet is the third data packet, the receiver processor 32 determines if the timer exceeds the threshold and, if so, executes 275 the command and restarts the reception method 200. However, if the timer does not exceed the threshold, the receiver processor 32 restarts the reception method 200.

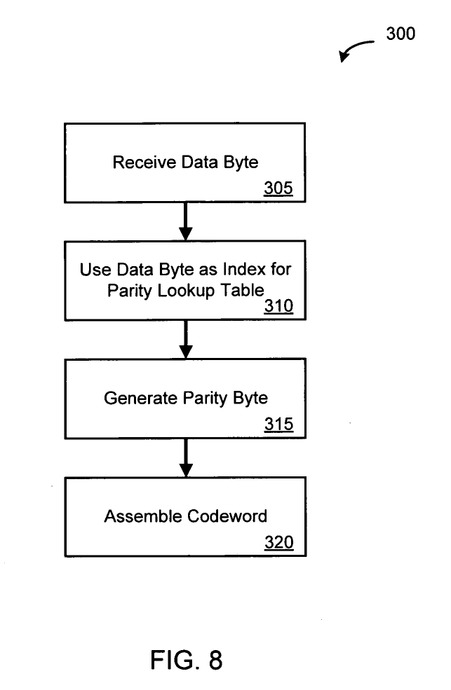

FIG. 8 illustrates one embodiment of an error encoding method 300. The depicted error encoding method 300 begins and the parity generation apparatus 25 receives 305 a data byte or other unit of data. The parity generation apparatus 25 then uses 310 the data byte as an index for the parity lookup table and, subsequently, generates the parity byte 315. One example of the Nordstrom-Robinson parity lookup table with the data byte as an index is shown in Table 1 above. The parity generation apparatus 25 then assembles 320 the codeword including the data byte and the parity byte. The illustrated error encoding method 300 then ends.

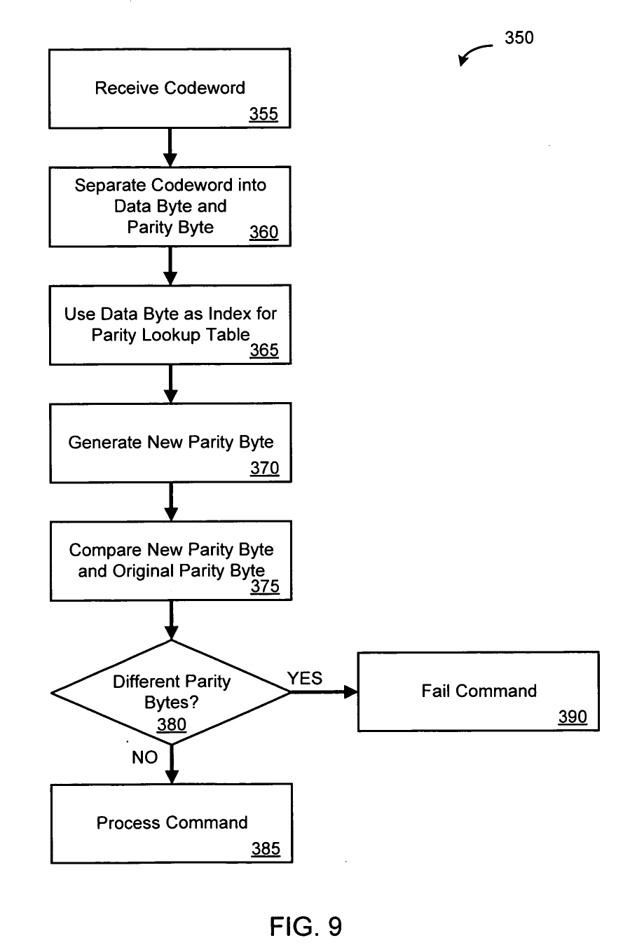

FIG. 9 illustrates one embodiment of an error decoding method 350. The depicted error decoding method 350 begins and the error detection apparatus 46 receives 355 the codeword including the data byte and the parity byte. The error detection apparatus 46 then separates 360 the parity byte from the data byte and uses 365 the data byte to generate 370 a new parity byte. In one embodiment, the error detection apparatus 46 uses 365 the data byte as an index for a parity lookup table such as the lookup tables 115, 130. One example of the Nordstrom-Robinson parity lookup table with the data byte as an index is shown in Table 1 above.

The error detection apparatus 46 subsequently compares 375 the transmitted parity byte and the new parity byte to determine 380 if there is a difference between the two parity bytes. If there is not a difference, then the error detection apparatus 46 may so indicate and the controlled device 40 may process 385 the received command. Otherwise, if there is a difference between the transmitted and new parity bytes, then the error detection apparatus 46 fails 390 the transmission. In another embodiment, the error detection apparatus 46 also may implement error correction techniques to correct an error in the transmitted data, in which case the error detection apparatus 46 may allow the command to be processed 385. The illustrated error decoding method 350 then ends.

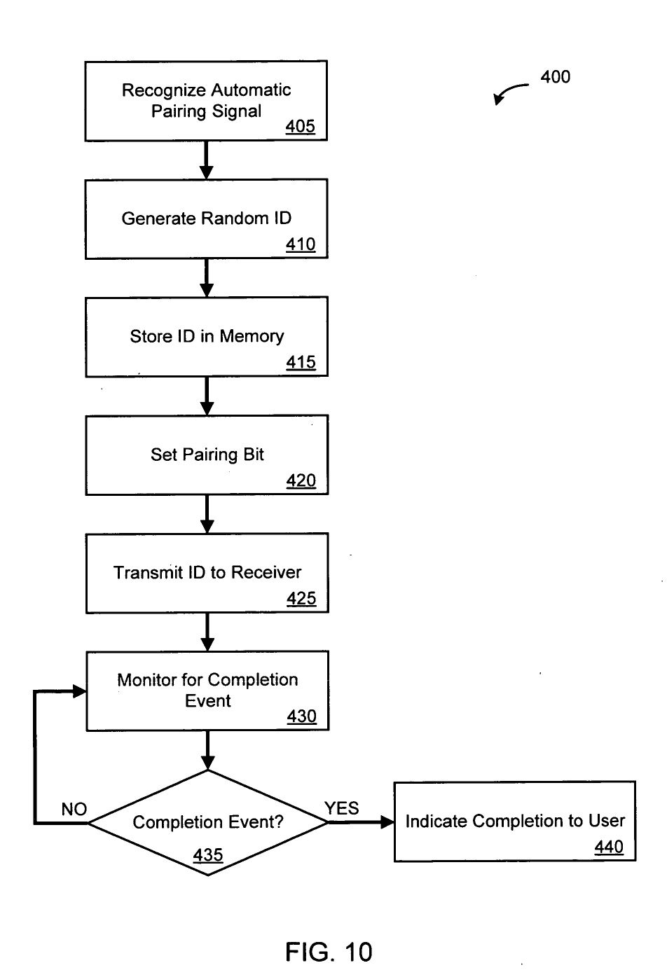

FIG. 10 illustrates one embodiment of an automatic pairing method 400. In general, a pairing process may be performed to associate a given transmitter unit 20 with a given receiver unit 30. In particular, the pairing process associates a unique transmitter address with the transmitter unit 20 and communicates that transmitter address to the receiver unit 30. In this way, the receiver unit 30 may distinguish between communications from the transmitter unit 20 and other communications or interference external to the communication system 10. In one embodiment, the transmitter address may be stored on the memory device 26 on the transmitter unit 20 and on a similar memory device (not shown) on the receiver unit 30. Alternatively, the transmitter address may be stored on another data storage or memory device on the transmitter unit 20 and/or the receiver unit 30.

The illustrated automatic pairing method 400 begins and the transmitter receiver 32 recognizes 405 an automatic pairing signal to initiate an automatic pairing mode. In one embodiment, a user may generate the automatic pairing signal. For example, the user may press a combination of buttons (e.g., simultaneously press and hold two keypad buttons for three seconds) to enter the automatic pairing mode. Any combination of simultaneous or sequential button presses and/or holds may be used. The initiation of the automatic pairing mode may cause the transmitter unit 20 to communicate an automatic pairing command to the receiver unit 30. For example, the transmitter unit 20 may communicate the command 100000000000 during the time one or more buttons are depressed on the transmitter keypad. In one embodiment, the packet with the automatic pairing command may be identified with a default transmitter address or a previous transmitter address. Additionally, the transmitter unit 20 may indicate to the user via the indicator 28 that the transmitter unit 20 is in the automatic pairing mode. For example, an LED may turn off and remain off during the time the buttons are depressed on the transmitter keypad. Subsequently, the LED may blink twice and remain on during the remainder of the automatic pairing method 400. Alternative indication operations may be used in place of or in addition to the described operations.

The transmitter processor 22 then generates 410 a random identifier to be used as or associated with the new transmitter address. The transmitter processor 22 then stores 415 the remote identifier in a storage or memory device such as the memory device 26. In one embodiment, the random identifier is between 1 and 255 and generated by a fast running counter that may be stopped by a key press by the user. Although a mathematical random number generator may be employed to assist in generating the random identifier, some user interaction may be beneficial to generate random numbers that might not be possible using a standard random number seed.

In subsequent communications from the transmitter unit 20 to the receiver unit 30, the transmitter unit 20 may set 420 a pairing bit within the command bits of the data packet. Additionally, the transmissions during the automatic pairing method 400 may be accompanied by a unique indication (e.g., a reverse blink) to indicate that the transmitter unit 20 is in the automatic pairing mode.

The transmitter unit 20 then transmits 425 the random identifier (or the transmitter address itself, if different from the random identifier) to the receiver unit. The transmitter unit 20 may subsequently monitor 430 for a completion event such as a timeout (e.g., one minute) or an acknowledgement from the receiver unit 30, and upon recognizing 435 the completion event the transmitter unit 20 indicates 440 the completion of the automatic pairing method 400 to the user. For example, the LED may turn off. Alternatively, the completion event may be initiated by the user by pressing a button on the transmitter unit 20. The illustrated automatic pairing method 400 then ends.

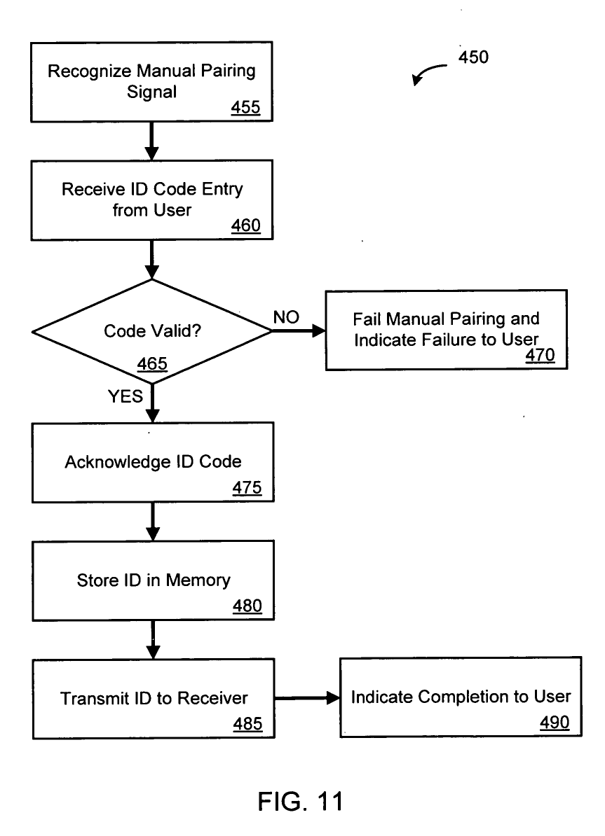

FIG. 11 illustrates one embodiment of a manual pairing method 450. The manual pairing method 450 may be implemented instead of the automatic pairing method 400 or if, for some reason, the automatic pairing method 400 is unsuccessful. For example, a user may experience interference from another remote control system that prevents the automatic pairing method 400 from pairing the transmitter unit 20 with the receiver unit 30.

The illustrated manual pairing method 450 begins and the transmitter processor 22 recognizes 455 a manual pairing signal to initiate a manual pairing mode. In one embodiment, a user may generate the manual pairing signal. For example, the user may press a combination of buttons (e.g., simultaneously press and hold two keypad buttons for three seconds) to enter the manual pairing mode. This combination is different from any combination that may be used to initiate the automatic pairing method 400. However, the initiation actions of the user and the operations of the transmitter unit 20 may be similar, in many ways, to the actions and operations of the automatic pairing method 400.

The transmitter processor 22 then receives 460 a user-specified identifier from the user. In one embodiment, the user may enter the identifier using a numeric keypad. After each button press by the user, an LED may reverse blink to acknowledge the entry. The transmitter processor 22 then determines 465 if the user-specified identifier is valid. In one embodiment, the user-specified identifier is valid if it corresponds to a predetermined identifier or is within a predetermined range of identifiers. If the user-specified identifier is not valid, the transmitter processor 22 fails 470 the manual pairing process and indicates the failure to the user. Otherwise, if the user-specified identifier is valid, the transmitter unit 20 acknowledges 475 the entry (e.g., the LED blinks twice and turns off) and stores 480 the user-specified identifier in a storage or memory device such as the memory device 26.

The transmitter unit 20 subsequently transmits 485 the user-specified identifier (or a corresponding transmitter address) to the receiver unit 30 and indicates 490 completion of the manual pairing method 450 to the user. The illustrated manual pairing method 450 then ends.

Certain embodiments of the method, apparatus, and system described above offer advantages, compared to conventional technologies, including increased performance without increased production hardware costs. In this way, relatively low-cost transmitter and receiver hardware (compared to multi-frequency hardware) may be used to provide at least equal or better command integrity than conventional IR and RF remote control devices.

Although the operations of the method(s) herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

The digital processing device(s) described herein may include one or more general-purpose processing devices such as a microprocessor or central processing unit, a controller, or the like. Alternatively, the digital processing device may include one or more special-purpose processing devices such as a digital signal processor (DSP), an application specific integrated circuit (ASIC), a field programmable gate array (FPGA), or the like. In an alternative embodiment, for example, the digital processing device may be a network processor having multiple processors including a core unit and multiple microengines. Additionally, the digital processing device may include any combination of general-purpose processing device(s) and special-purpose processing device(s).

Certain embodiments may be implemented as a computer program product that may include instructions stored on a machine-readable medium. These instructions may be used to program a general-purpose or special-purpose processor to perform the described operations. A machine-readable medium includes any mechanism for storing or transmitting information in a form (e.g., software, processing application) readable by a machine (e.g., a computer). The machine-readable medium may include, but is not limited to, magnetic storage medium (e.g., floppy diskette); optical storage medium (e.g., CD-ROM); magneto-optical storage medium; read-only memory (ROM); random-access memory (RAM); erasable programmable memory (e.g., EPROM and EEPROM); flash memory; electrical, optical, acoustical, or other form of propagated signal (e.g., carrier waves, infrared signals, digital signals, etc.); or another type of medium suitable for storing electronic instructions.

Additionally, some embodiments may be practiced in distributed computing environments where the machine-readable medium is stored on and/or executed by more than one computer system. In addition, the information transferred between computer systems may either be pulled or pushed across the communication medium connecting the computer systems.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative sense rather than a restrictive sense.

What is claimed is:

1. A method, comprising:
assembling data for communication from a transmitter unit to a receiver unit in a wireless remote control system;
generating a parity code and associating the parity code with the data, wherein the parity code and the data comprise an error code; and
transmitting the data and the error code from the transmitter unit to the receiver unit.

2. The method of claim 1, wherein generating the error code comprises generating a Nordstrom-Robinson code.

3. The method of claim 1, wherein the error code is substantially DC-balanced.

4. The method of claim 1, wherein the error code is systematic.

5. The method of claim 1, further comprising at least partially interleaving the parity code and the data.

6. The method of claim 1, wherein the data comprises a transmitter address, a packet repetition indicator, and a command.

7. The method of claim 1, further comprising modulating the electromagnetic signal using amplitude shift keying (ASK), frequency shift keying (FSK), or frequency modulation (FM).

8. The method of claim 1, wherein transmitting the electromagnetic signal comprises transmitting an infrared signal or a radio frequency signal.

9. A machine readable medium having instructions thereon, which instructions, when executed by a digital processing device, cause the digital processing device to perform the operations of claim 1.

10. An apparatus, comprising:
a receiver to receive an electromagnetic signal from a transmitter in a wireless remote control system, the electromagnetic signal comprising data and a parity code, wherein the data and the parity code comprise an error code; and
a digital processing device coupled to the receiver, the digital processing device to communicate the data and the parity code to a parity detection apparatus coupled to the digital processing device to determine if the data contains an error according to the error code.

11. The apparatus of claim 10, wherein the error code comprises a Nordstrom-Robinson code.

12. The apparatus of claim 11, wherein the parity code is interleaved with the data and the digital processing device is further configured to separate the data and the parity code.

13. A system comprising the apparatus of claim 10, the system further comprising a parity generation apparatus coupled to the transmitter, the parity generation apparatus to generate the error code.

14. A system comprising the apparatus of claim 10, the system further comprising a memory device coupled to the parity detection apparatus, the memory device to store an error encoding table.

15. The system of claim 14, further comprising a controlled device coupled to the digital processing device, the controlled device to receive the data from the digital processing device and to perform an operation according to the data in response to a determination that the data is free of transmission errors.

16. The system of claim 15, wherein the parity detection apparatus is located on the controlled device.

17. An apparatus, comprising:
a digital processing device to generate a data packet comprising data;
a parity generation apparatus coupled to the digital processing device, the parity generation apparatus to generate a parity code associated with the data, wherein the data and the parity comprise an error code and the data packet further comprises the error code; and
a transmitter coupled to the digital processing device, the transmitter to transmit an electromagnetic signal corresponding to the data packet to a receiver in a wireless remote control system.

18. The apparatus of claim 17, further comprising a memory device coupled to the digital processing device, the memory device to store an error encoding table.

19. The apparatus of claim 18, wherein the error encoding table comprises an encoding table for a Nordstrom-Robinson code.

20. The apparatus of claim 17, wherein the digital processing device is configured to at least partially interleave the data and the parity code.

21. The apparatus of claim 17, wherein the data further comprises a transmitter address, a packet repetition indicator, and a command.

22. The apparatus of claim 17, wherein the transmitter comprises an analog, single carrier transmitter to modulate the electromagnetic signal using amplitude shift keying (ASK), frequency shift keying (FSK), or frequency modulation (FM).

23. The apparatus of claim 17, wherein the electromagnetic signal comprises an infrared signal or a radio frequency signal.

24. The apparatus of claim 17, further comprising:
a memory device coupled to the digital signal processor, the memory device to store a transmitter address;
an input device coupled to the digital signal processor, the input device to receive a user input; and
an indicator coupled to the digital signal processor, the indicator to communicate an audible signal or a visible signal or both to a user.

25. An apparatus, comprising:
means for generating a data packet;
means for transmitting the data packet from a transmitter unit to a receiver unit in a wireless remote control system; and
means for verifying data parity of the data packet in response to receiving the data packet at the receiver unit.

26. The apparatus of claim 25, wherein the means for verifying data parity comprise means for transmitting a parity code with the data packet.

27. The apparatus of claim 26, further comprising means for interleaving the data and the parity code.

28. The apparatus of claim 26, further comprising means for generating a Nordstrom-Robinson code comprising the data and the parity code.
